(19) United States
(12) Patent Application Publication
(10) Pub. No.: US 2013/0070801 A1
(43) Pub. Date: Mar. 21, 2013

(54) SEMICONDUCTOR LASER DEVICE AND METHOD OF MANUFACTURING THE SAME

(71) Applicants: Yoshiki MURAYAMA, Hirakata-shi (JP); Shingo Kameyama, Ibaraki-shi (JP); Yasuhiko Nomura, Osaka-shi (JP)

(72) Inventors: Yoshiki MURAYAMA, Hirakata-shi (JP); Shingo Kameyama, Ibaraki-shi (JP); Yasuhiko Nomura, Osaka-shi (JP)

(73) Assignee: Sanyo Electric Co., Ltd., Moriguchi-shi (JP)

(21) Appl. No.: 13/675,779

(22) Filed: Nov. 13, 2012

Related U.S. Application Data
(62) Division of application No. 12/608,549, filed on Oct. 29, 2009.

(51) Int. Cl. H01S 5/10; H01L 33/44

(52) U.S. Cl. 372/49.01; 438/22; 257/E33.06

(57) ABSTRACT

A semiconductor laser device includes a first cavity facet formed on an end of the semiconductor element layer on a light-emitting side of a region including the light emitting layer, a first insulating film, made of AlN, formed on a surface of the first cavity facet and a second insulating film, made of AlO_{X}N_{Y} (0≦X<1.5, 0≦Y≦1), formed on a surface on an opposite side of the first insulating film to the first cavity facet. A first interface between the first insulating film and the second insulating film has a first recess portion and a first projection portion.

### CROSS-REFERENCE TO RELATED APPLICATIONS

This application is a divisional of pending U.S. application Ser. No. 12/608,549 filed Oct. 29, 2010 and claims priority to Japanese application number JP2008-279562, entitled, “Semiconductor Laser Device and Method of Manufacturing the Same”, filed Oct. 30, 2008, Yoshiki Murayama et al, the disclosure of which is incorporated herein, in its entirety by reference.

### BACKGROUND OF THE INVENTION

1. Field of the Invention

The present invention relates to a semiconductor laser device and a method of manufacturing the same, and more particularly, it relates to a semiconductor laser device including a semiconductor element layer having a light emitting layer and a method of manufacturing the same.

2. Description of the Background Art

In general, a semiconductor laser is widely employed as the light source of an optical disk system or an optical communication system. Following improvement in performance of apparatuses constituting the system, characteristic improvement of the semiconductor laser is demanded. In particular, wavelength shortening and higher output of a laser beam are desired as the light source of a high-density optical disk system, and a blue-violet semiconductor laser having a lasing wavelength of about 405 nm has recently been developed with a nitride-based semiconductor, while higher output thereof is examined.

A semiconductor laser device allowing higher output by subjecting cavity facets of the laser device to facet coating treatment is proposed in general. Such a semiconductor laser device is disclosed in Japanese Patent Laying-Open No. 2007-201373, for example.

The aforementioned Japanese Patent Laying-Open No. 2007-201373 discloses a semiconductor laser device in which a first dielectric film made of an oxide film and a second dielectric film made of a nitride film or an oxynitride film are stacked in this order on a cavity facet on a light-emitting side. In the semiconductor laser device described in Japanese Patent Laying-Open No. 2007-201373, adhesiveness between the first dielectric film and the second dielectric film is improved by forming the second dielectric film similar in thermal expansion coefficient to the first dielectric film on the outer side of the first dielectric film, and heat radiability of the semiconductor laser device is improved by the second dielectric film made of the oxynitride film containing nitrogen, and hence higher output of the laser beam can be achieved. In this semiconductor laser device, attempt to employ the nitride film having higher thermal conductivity than the oxide film for the first dielectric film has been made in order to further improve the heat radiability of the dielectric multilayer film.

In the semiconductor laser device disclosed in the aforementioned Japanese Patent Laying-Open No. 2007-201373, the second dielectric film similar in thermal expansion coefficient to the first dielectric film is formed on the outer side of the first dielectric film, whereby adhesiveness between the dielectric films are conceivably improved to some extent. In the semiconductor laser device for which higher output is demanded, on the other hand, the dielectric films tend to separate due to heat generation or heat absorption in the cavity facet, and hence improvement in the adhesiveness between the dielectric films is further demanded.

### SUMMARY OF THE INVENTION

A semiconductor laser device according to a first aspect of the present invention comprises a semiconductor element layer having a light emitting layer, a first cavity facet formed on an end of the semiconductor element layer on a light-emitting side of a region including the light emitting layer, a first insulating film, made of AlN, formed on a surface of the first cavity facet a second insulating film, made of AlO_{X}N_{Y} (0≦X<1.5, 0≦Y≦1), formed on a surface on an opposite side of the first insulating film to the first cavity facet, wherein a first interface between the first insulating film and the second insulating film has a first recess portion and a first projection portion.

In the present invention, the first cavity facet formed on the end on the light-emitting side is distinguished by the large-small relation between the intensity levels of laser beams emitted from a pair of cavity facets formed on the ends of the semiconductor laser device. In other words, the side on which the emission intensity of the laser beam is relatively large is the first cavity facet on the light-emitting side, while the side on which the emission intensity of the laser beam is relatively small is a second cavity facet on a light-reflecting side. In the present invention, as to combination of an oxygen composition ratio (X) and a nitrogen composition ratio (Y) constituting AlO_{X}N_{Y} of the second insulating film, for example, when Y approaches zero without limit, X approaches 1.5 without limit. In this case, the mechanical property of the second insulating film (AlO_{X}N_{Y} film) approaches the Al₂O₃ film without limit, and hence the range of the oxygen composition ratio (X) is specified as 0≦X≦1.5.

As hereinabove described, the semiconductor laser device according to the first aspect of the present invention comprises the first insulating film, made of AlN, formed on the surface of the first cavity facet and the second insulating film made of AlO_{X}N_{Y}, and the first interface between the first insulating film and the second insulating film has roughness, whereby the first insulating film and the second insulating film are in contact with each other on the first interface having the roughness, and hence the first insulating film and the second insulating film can be in contact with each other through a wider surface area due to formation of the roughness as compared with a case where the first insulating film and the second insulating film are in contact with each other on an flat contact interface with no roughness. Thus, adhesiveness between the dielectric films can be further improved.

The semiconductor laser device comprises the first insulating film, made of AlN, formed on the surface of the first cavity facet and the second insulating film made of AlO_{X}N_{Y} film, whereby reflectance for the laser beam emitted from the first cavity facet can be easily controlled by adjusting the thickness of the second insulating film. Thus, the semiconductor laser device allowing higher output can be easily formed.

In the aforementioned semiconductor laser device according to the first aspect, a maximum value H1 of a height from a bottom portion of the first recess portion to a top portion of the first projection portion adjacent to the first recess portion on the first interface is preferably set to H1 <λ/n1 and H1<λ/n2 when a wavelength of a laser beam emitted by the light emitting layer is λ and average refractive indices of the first insulating film and the second insulating film are n1 and n2, respectively. According to this structure, the size of the pluralities of projecting and recess portions on the first interface (height of undulation) is smaller than λ/n1 and λ/n2. Thus, the laser beam emitted from the first cavity facet is transmitted through the interface without being influenced by the state of the roughness and then transmitted through the second insulating film. Consequently, the reflectance control function of the second insulating film set to have a desirable reflectance can be easily inhibited from being influenced by the roughness of the first interface.

According to the aforementioned structure, the reflectance for the laser beam on the interface between AlN and AlO_{X}N_{Y} is reduced, and hence the laser beam can be effectively emitted from the first cavity facet.

In the aforementioned semiconductor laser device according to the first aspect, the AlO_{X}N_{Y} preferably satisfies X<Y. According to this structure, the second insulating film can be formed on the first insulating film in the state where the interface between the second insulating film and the first insulating film has the roughness, when the cavity facet is subjected to the facet coating treatment. Consequently, the second insulating film can be formed in a state where adhesiveness with the first insulating film is excellent. According to the aforementioned structure, the quantity of diffusion of oxygen contained in the second insulating film to the first insulating film can be suppressed. Thus, diffusion of oxygen from the first insulating film to the semiconductor element layer is suppressed, and hence catastrophic optical damage (COD) on the first cavity facet can be suppressed.

In the aforementioned semiconductor laser device according to the first aspect, a thickness of the first insulating film is preferably smaller than that of the second insulating film. According to this structure, the thickness of the first insulating film made of the nitride film is smaller than that of the second insulating film made of the oxynitride film, and hence stress of the first insulating film (nitride film) in contact with the first cavity facet can be kept small. Thus, separation of the first insulating film from the first cavity facet or separation of the second insulating film from the first insulating film can be suppressed.

The aforementioned semiconductor laser device according to the first aspect preferably further comprises a third insulating film, made of either an oxide film or a nitride film, formed on a surface on an opposite side of the second insulating film to the first cavity facet. According to this structure, the reflectance for the laser beam emitted from the first cavity facet can be easily controlled by adjusting the thickness of the third insulating film. Thus, the semiconductor laser device allowing higher output can be easily formed.

In the aforementioned structure in which the semiconductor laser device further comprises the third insulating film, the second insulating film and the third insulating film preferably contain the same metal element. According to this structure, the second insulating film and the third insulating film which are in contact with each other are materials containing the same kind of metal element, and hence adhesiveness when the second insulating film and the third insulating film are in contact with each other can be improved.

In this case, the second insulating film and the third insulating film preferably each contain Al. According to this structure, the insulating properties of the second insulating film and the third insulating film can be improved since a nitride and an oxide containing Al each have an excellent insulating property. When the nitride film containing Al is employed, incorporation of oxygen into the first insulating film and the semiconductor element layer can be effectively suppressed.

The aforementioned semiconductor laser device according to the first aspect preferably further comprises a second cavity facet formed on an end of the semiconductor element layer on a light-reflecting side of a region including the light emitting layer, a fourth insulating film, made of AlN, formed on a surface of the second cavity facet, and a fifth insulating film, made of AlO_{X}N_{Y} (0≦X<1.5, 0<Y≦1), formed on a surface on an opposite side of the fourth insulating film to the second cavity facet, wherein a second interface between the fourth insulating film and the fifth insulating film has a second recess portion and a second projection portion. According to this structure, the fourth insulating film and the fifth insulating film are in contact with each other on the second interface having the roughness, and hence the fourth insulating film and the fifth insulating film can be in contact with each other through a wider surface area due to formation of the roughness as compared with a case where the fourth insulating film and the fifth insulating film are in contact with each other on an flat contact interface with no roughness. Thus, adhesiveness between the dielectric films can be further improved also on the second cavity facet. The semiconductor laser device comprises the fourth insulating film, made of AlN, formed on the surface of the second cavity facet film and the fifth insulating film, made of AlO_{X}N_{Y}, whereby reflectance for the laser beam emitted from the second cavity facet can be easily controlled by adjusting the thickness of the fifth insulating film. Thus, the semiconductor laser device allowing higher output can be easily formed.

In the aforementioned structure in which the semiconductor laser device further comprises the second cavity facet, a maximum value H2 of a height from a bottom portion of the second recess portion to a top portion of the second projection portion adjacent to the second recess portion on the second interface is set to H2<λ/n3 and H2<λ/n4 when a wavelength of a laser beam emitted by the light emitting layer is λ and average refractive indices of the fourth insulating film and the fifth insulating film are n3 and n4, respectively. According to this structure, the size of the pluralities of projecting and recess portions on the second interface (height of undulation) is smaller than λ/n3 and λ/n4. Thus, the laser beam emitted from the second cavity facet can be transmitted through the interface without being influenced by the state of the roughness and then transmitted through the fifth insulating film. Consequently, the reflectance control function of the fifth insulating film set to have a desirable reflectance can be easily inhibited from being influenced by the roughness of the second interface.

In the aforementioned structure in which the semiconductor laser device further comprises the second cavity facet, the AlO_{X}N_{Y} preferably satisfies X<Y. According to this structure, the fifth insulating film can be formed on the fourth insulating film in the state where the interface between the fifth insulating film and the fourth insulating film has the roughness, when the second cavity facet is subjected to the facet coating treatment. Consequently, the fifth insulating film can be formed in a state where adhesiveness with the fourth insulating film is excellent. According to the aforementioned structure, the quantity of diffusion of oxygen contained in the fifth insulating film to the fourth insulating film can be suppressed. Thus, diffusion of oxygen from the fourth insulating film to the semiconductor element layer is suppressed, and hence COD on the second cavity facet can be suppressed.

In the aforementioned structure in which the semiconductor laser device further comprises the second cavity facet, a thickness of the fourth insulating film is preferably smaller than that of the fifth insulating film. According to this structure, the thickness of the fourth insulating film made of the nitride film is smaller than that of the fifth insulating film made of the oxynitride film, and hence stress of the fourth insulating film (nitride film) in contact with the second cavity facet can be kept small. Thus, separation of the fourth insulating film from the second cavity or separation of the fifth insulating film from the fourth insulating film can be suppressed.

In the aforementioned structure in which the semiconductor laser device further comprises the second cavity facet, the semiconductor laser device preferably further comprises a sixth insulating film, including at least any of an oxide film, a nitride film and an oxynitride film, formed on a surface on an opposite side of the fifth insulating film to the second cavity facet. According to this structure, the reflectance for the laser beam emitted from the second cavity facet can be easily controlled by adjusting the thickness of the sixth insulating film. Thus, the semiconductor laser device allowing higher output can be more easily formed.

In the aforementioned structure in which the semiconductor laser device further comprises the sixth insulating film, the fifth insulating film and the sixth insulating film preferably contain the same metal element. According to this structure, the fifth insulating film and the sixth insulating film which are in contact with each other are materials containing the same kind of metal element, and hence adhesiveness when the fifth insulating film and the sixth insulating film are in contact with each other can be improved.

In this case, the fifth insulating film and the sixth insulating film preferably each contain Al. According to this structure, the insulating properties of the fifth insulating film and the sixth insulating film can be improved since a nitride and an oxide containing Al each have an excellent insulating property. When the nitride film containing Al is employed, incorporation of oxygen into the fourth insulating film and the semiconductor element layer can be effectively suppressed.

In the aforementioned structure in which the semiconductor laser device further comprises the sixth insulating film, the semiconductor laser device preferably further comprises a seventh insulating film, made of a multilayer reflecting film, formed on a surface on an opposite side of the sixth insulating film to the second cavity facet. According to this structure, reflectance for the laser beam emitted from the second cavity facet on the light-reflecting side can be easily controlled by adjusting the thickness of the seventh insulating film.

A method of manufacturing a semiconductor laser device according to a second aspect of the present invention comprises steps of forming a semiconductor element layer having a light emitting layer, forming cavity facets on ends of the semiconductor element layer on a region including the light emitting layer, and forming a first insulating film made of AlN and a second insulating film made of AlO_{X}N_{Y} (0≦X<1.5, 0<Y≦1) from the cavity facet side on a surface of the facet on the light-emitting side in the cavity facets so that an interface between the first insulating film and the second insulating film has a first recess portion and a first projection portion.

As hereinabove described, the method of manufacturing a semiconductor laser device according to the second aspect of the present invention comprises the step of forming the first insulating film made of AlN and the second insulating film made of AlO_{X}N_{Y} from the surface side of the cavity facet on the surface of the facet on the light-emitting side so that the interface between the first insulating film and the second insulating film has the roughness, whereby the first insulating film and the second insulating film are in contact with each other on the interface having the roughness, and hence the first insulating film and the second insulating film can be in contact with each other through a wider surface area due to formation of the roughness as compared with a case where the first insulating film and the second insulating film are in contact with each other on an flat contact interface with no roughness. Thus, adhesiveness between the dielectric films can be further improved.

In the aforementioned method of manufacturing the semiconductor laser device according to the second aspect, the step of forming the first insulating film and the second insulating film preferably includes a step of forming the first insulating film and the second insulating film by ECR plasma. According to this structure, the first insulating film and the second insulating film can be formed so that the interface between the first insulating film and the second insulating film easily has the roughness.

In the aforementioned structure including the step of forming the first insulating film and the second insulating film by ECR plasma, the step of forming the first insulating film and the second insulating film preferably includes a step of forming the first insulating film on the surface of the cavity facet in a state where ECR plasma is generated in an N₂ gas atmosphere, and a step of forming the second insulating film on a surface of the first insulating film formed with the first recess portion and the first projection portion while forming the first recess portion and the first projection portion on the surface of the first insulating film by forming the second insulating film on the surface of the first insulating film in a state where ECR plasma is generated in an atmosphere N₂ and O₂ gas. According to this structure, the second insulating film covering this roughness can be easily stacked while forming the roughness on the surface of the first insulating film when forming the second insulating film.

In this case, the second insulating film is preferably formed on the surface of the first insulating film in a state where the ECR plasma is generated by applying high-frequency power when forming the second insulating film on the surface of the first insulating film. According to this structure, the roughness for adhering the second insulating film to the surface of the first insulating film can be easily formed.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view of a nitride-based semiconductor laser device on a surface along a cavity direction, for illustrating a structure of the nitride-based semiconductor laser device according to a first embodiment of the present invention;

FIG. 2 is a sectional view showing the structure of the nitride-based semiconductor laser device according to the first embodiment of the present invention;

FIG. 3 is an enlarged sectional view showing the structure of the nitride-based semiconductor laser device according to the first embodiment of the present invention;

FIG. 4 is a sectional view of a semiconductor laser device on a surface along a cavity direction, for illustrating a structure of the semiconductor laser device according to a second embodiment of the present invention;

FIG. 5 is an enlarged sectional view showing the structure of the nitride-based semiconductor laser device according to the second embodiment of the present invention;

FIG. 6 is a sectional view of a semiconductor laser device on a surface along a cavity direction, for illustrating a structure of the semiconductor laser device according to a first modification of the second embodiment of the present invention;

FIG. 7 is a sectional view of a semiconductor laser device on a surface along a cavity direction, for illustrating a structure of the semiconductor laser device according to a second modification of the second embodiment of the present invention;

FIG. 8 is a sectional view of a semiconductor laser device on a surface along a cavity direction, for illustrating a structure of the semiconductor laser device according to a third modification of the second embodiment of the present invention;

FIG. 9 is a sectional view of a semiconductor laser device on a surface along a cavity direction, for illustrating a structure of the semiconductor laser device according to a third embodiment of the present invention;

FIGS. 10 and 11 are photomicrographs obtained when a state of a dielectric multilayer film formed on a light emitting surface side of the nitride-based semiconductor laser device according to the first embodiment of the present invention was observed with a TEM; and

FIGS. 12 and 13 are diagrams showing a result of a confirmatory experiment conducted for comfirming the effects of the first embodiment of the present invention.

### DESCRIPTION OF THE PREFERRED EMBODIMENTS

### Embodiments

Embodiments of the present invention will be hereinafter described with reference to the drawings.

### First Embodiment

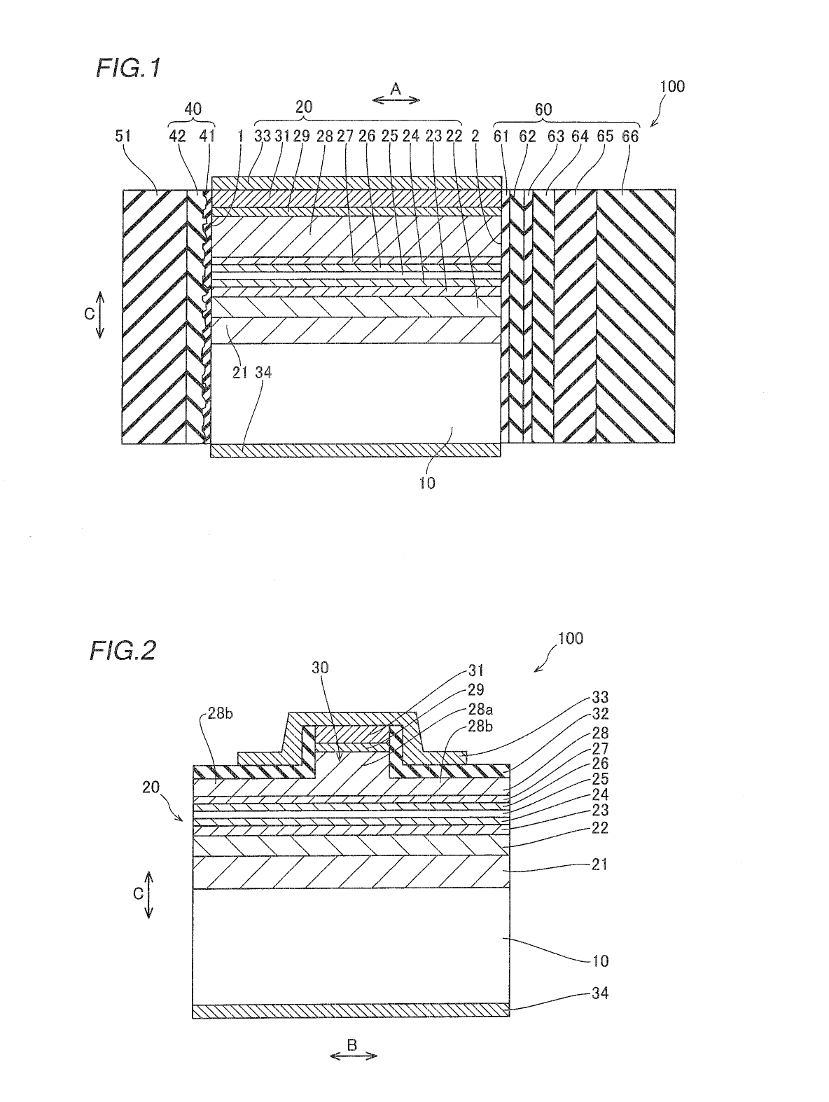

A structure of a nitride-based semiconductor laser device 100 according to a first embodiment of the present invention will be now described with reference to FIGS. 1 to 3.

In the nitride-based semiconductor laser device 100 according to the first embodiment of the present invention, a semiconductor element layer 20 having a lasing wavelength of about 405 nm is formed on a surface of an oxygen-doped n-type (0001) plane GaN substrate 10 having a thickness of about 100 μm and having a carrier concentration of about 5×10¹⁸ cm⁻³, as shown in FIG. 2.

In the nitride-based semiconductor laser device 100, a light emitting surface 1 and a light reflecting surface 2 are formed on respective both end portions in a cavity direction (direction A), as shown in FIG. 1. The light emitting surface 1 is an example of the “facet on a light-emitting side” in the present invention. Dielectric multilayer films 40 and 60 are formed on the light emitting surface 1 and the light reflecting surface 2 of the nitride-based semiconductor laser device 100, respectively, by facet coating treatment in a manufacturing process. The light emitting surface 1 is an example of the “first cavity facet” in the present invention.

According to the first embodiment, the dielectric multilayer film 40 in which an AlN film 41 having a thickness of about 10 nm in contact with the light emitting surface 1 and an AlO_{X}N_{Y} film 42 having a thickness of about 30 nm in contact with the AlN film 41 are formed successively from a side closer to the light emitting surface 1 is formed on the light emitting surface 1 of the nitride-based semiconductor laser device 100, as shown in FIG. 1. Further, an Al₂O₃ film 51 having a thickness of about 60 nm in contact with the dielectric multilayer film 40 is formed. The AlN film 41 and the AlO_{X}N_{Y} film 42 are examples of the “first insulating film” and the “second insulating film” in the present invention, respectively, and the Al₂O₃ film 51 is an example of the “third insulating film” in the present invention. According to the first embodiment, the AlN film 41 and the AlO_{X}N_{Y} film 42 are enabled to suppress alteration of the dielectric multilayer film 40 itself and the light emitting surface 1 due to a thermal influence or light absorption following emission of a laser beam. The Al₂O₃ film 51 has a function of controlling a reflectance, and the light emitting surface 1 side is set to have a reflectance of about 8% for a laser beam due to the Al₂O₃ film 51.

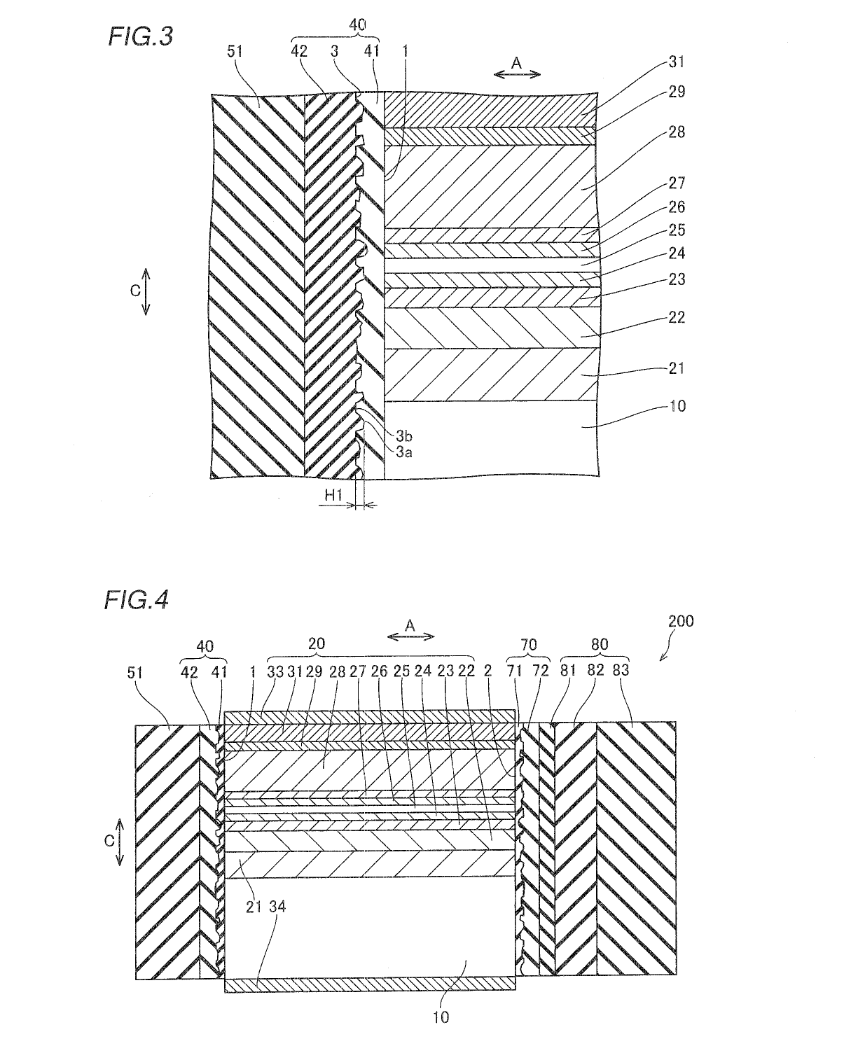

According to the first embodiment, when an interface 3 on which the AlN film 41 and the AlO_{X}N_{Y} film 42 are in contact with each other is microscopically viewed, the interface 3 has roughness by a plurality of recess portions 3a and a plurality of projecting portions 3b as viewed from the AlO_{X}N_{Y} film 42 side, as shown in FIG. 3. In other words, the plurality of projecting portions or recess portions formed on the AlO_{X}N_{Y} film 42 are fitted into the plurality of recess portions or projecting portions formed on the AlN film 41 with no clearance, thereby forming the roughness of the interface 3. Therefore, the pluralities of recess portions 3a and projecting portions 3b of the interface 3 in FIG. 3 are the pluralities of recess portions and projecting portions which the AlN film 41 has as well as the pluralities of projecting portions and recess portions which the AlO_{X}N_{Y} film 42 has, and this shows that the AlN film 41 and the AlO_{X}N_{Y} film 42 are in contact with each other on the interface 3 in an improved adhesive state. The interface 3 is an example of the “first interface” in the present invention.

This roughness is formed to have planar spread along a width direction (direction B in FIG. 2) and a thickness direction (direction C) of the laser device formed with the light emitting surface 1 on the interface 3 where the AlN film 41 and the AlO_{X}N_{Y} film 42 are in contact with each other.

A maximum value H1 (see FIG. 3) of a height from a bottom portion of each recess portion 3a to a top portion of the projecting portion 3b forming the interface 3 is set to preferably have the relations of H1<λ/n1 and H1<λ/n2, when refractive indices of the AlN film 41 and the AlO_{X}N_{Y} film 42 are n1 (=about 2.10) and n2 (=value in the range of about 1.60 to about 2.10 (because AlO_{X}N_{Y} satisfies 0≦X<1.5 and 0<Y≦1)), respectively. According to the first embodiment, therefore, the roughness is so formed that an average value of the height from the bottom portion of each recess portion 3a to the top portion of the projecting portion 3b is about 5 nm. Thus, the laser beam emitted from the light emitting surface 1 can be emitted outside with no influence of the roughness of the interface.

The semiconductor element layer 20 having a lasing wavelength λ of about 405 nm is preferably so formed that the maximum value H1 of the height from the bottom portion of each recess portion 3a to the top portion of the projecting portion 3b forming the interface 3 is H1<about 193 nm.

According to the first embodiment, the AlO_{X}N_{Y} film 42 is so formed that a nitrogen composition ratio (Y) is higher than an oxygen composition ratio (X) (X<Y). Thus, the interface 3 between the AlN film 41 and the AlO_{X}N_{Y} film 42 is formed to easily have the roughness.

As shown in FIG. 1, a dielectric multilayer film 60 in which an AlN film 61 having a thickness of about 10 nm in contact with the light reflecting surface 2, an Al₂O₃ film 62 having a thickness of about 30 nm in contact with the AlN film 61, an AlN film 63 having a thickness of about 10 nm in contact with the Al₂O₃ film 62, an Al₂O₃ film 64 having a thickness of about 60 nm in contact with the AlN film 63, an SiO₂ film 65 having a thickness of about 140 nm in contact with the Al₂O₃ film 64, and a multilayer reflecting film 66, in contact with the SiO₂ film 65, having a thickness of about 720 nm, formed by alternately stacking six SiO₂ films each having a thickness of about 70 nm as a low refractive index film and six ZrO₂ films each having a thickness of about 50 nm as a high refractive index film are stacked is formed successively from a side closer to the light reflecting surface 2 on the light reflecting surface 2 of the nitride-based semiconductor laser device 100. The multilayer reflecting film 66 has a function of controlling a reflectance, and the light reflecting surface 2 side is set to have a high reflectance of about 98% for the laser beam due to the multilayer reflecting film 66.

In the semiconductor element layer 20, an n-type layer 21, made of Ge-doped n-type GaN having a doping quantity of about 5×10¹⁸ cm⁻³, having a thickness of about 100 nm is formed on the n-type (0001) plane GaN substrate 10, as shown in FIG. 2. An n-type cladding layer 22, made of Ge-doped n-type Al_{0.07}Ga_{0.93}N having a doping quantity of about 5×10¹⁸ cm⁻³ and a carrier concentration of about 5×10¹⁸ cm⁻³, having a thickness of about 400 nm is formed on the n-type layer 21.

An n-type carrier blocking layer 23, made of Ge-doped n-type Al_{0.16}Ga_{0.84}N having a doping quantity of about 5×10¹⁸ cm⁻³ and a carrier concentration of about 5×10¹⁸ cm⁻³, having a thickness of about 5 nm is formed on the n-type cladding layer 22. An n-side optical guide layer 24, made of undoped GaN, having a thickness of about 100 nm is formed on the n-type carrier blocking layer 23. An active layer 25 is formed on the n-side optical guide layer 24. This active layer 25 has an MQW structure in which four barrier layers made of undoped In_{0.02}Ga_{0.98}N each having a thickness of about 20 nm and three well layers made of undoped In_{0.1}Ga_{0.9}N each having a thickness of about 3 nm are alternately stacked.

As shown in FIG. 2, a p-side optical guide layer 26, made of undoped GaN, having a thickness of about 100 nm is formed on the active layer 25. A cap layer 27, made of undoped Al_{0.16}Ga_{0.84}N, having a thickness of about 20 nm is formed on the p-side optical guide layer 26.

A p-type cladding layer 28, made of p-type Al_{0.07}Ga_{0.93}N doped with Mg having a doping quantity of about 4×10¹⁹ cm⁻³ and a carrier concentration of about 5×10¹⁷ cm⁻³, having a projecting portion 28a and planar portions 28b other than the projecting portion 28a is formed on the cap layer 27. The planar portions 28b of the p-type cladding layer 28 each have a thickness of about 80 nm on both sides of the projecting portion 28a. A height from the planar portions 28b of the p-type cladding layer 28 to the projecting portion 28a is about 320 nm and a width of the projecting portion 28a is about 1.5 μm.

A p-side contact layer 29, made of undoped In_{0.02}Ga_{0.98}N, having a thickness of about 10 nm is formed on the projecting portion 28a of the p-type cladding layer 28. A ridge 30 is formed by the p-side contact layer 29 and the projecting portion 28a of the p-type cladding layer 28. The ridge 30 has a width of about 1.5 μm on the lower portion and is formed to extend in a [1-100] direction (direction A in FIG. 1). An optical waveguide extending in the [1-100] direction (direction A in FIG. 1) is formed on a portion including the active layer 25 located below the ridge 30. The n-type layer 21, the n-type cladding layer 22, the n-type carrier blocking layer 23, the n-side optical guide layer 24, the p-side optical guide layer 26, the cap layer 27, the p-type cladding layer 28 and the p-side contact layer 29 are each an example of the “semiconductor element layer” in the present invention. The active layer 25 is an example of the “light emitting layer” or the “semiconductor element layer” in the present invention.

As shown in FIG. 2, a p-side ohmic electrode 31 in which a Pt layer having a thickness of about 5 nm, a Pd layer having a thickness of about 100 nm and an Au layer having a thickness of about 150 nm are formed successively from the lower layer side is formed on the p-type contact layer 29 constituting the ridge 30. A current blocking layer 32, made of SiO₂, having a thickness of about 250 nm is formed on a region other than an upper surface of the p-side ohmic electrode 31. Further, a p-side pad electrode 33 in which a Ti layer having a thickness of about 100 nm, a Pd layer having a thickness of about 100 nm and an Au layer having a thickness of about 3 μm are formed successively from the lower layer side is formed on a prescribed region of the current blocking layer 32, to be in contact with the upper surface of the p-side ohmic electrode 31.

As shown in FIG. 2, an n-side electrode 34 in which an Al layer having a thickness of about 10 μm, a Pt layer having a thickness of about 20 nm and an Au layer having a thickness of about 300 nm are formed successively from a lower surface side of the n-type (0001) plane GaN substrate 10 is formed on the lower surface of the n-type (0001) plane GaN substrate 10.

A manufacturing process for the nitride-based semiconductor laser device 100 according to the first embodiment will be now described with reference to FIGS. 1 to 3.

As shown in FIG. 2, the n-type layer 21, the n-type cladding layer 22, the n-type carrier blocking layer 23, the n-side optical guide layer 24 and the active layer 25 are successively formed on the n-type (0001) plane GaN substrate 10 by MOVPE. The p-side optical guide layer 26, the cap layer 27, the p-type cladding layer 28 and the p-side contact layer 29 are successively formed on the active layer 25. Thereafter, the p-side ohmic electrode 31, the current blocking layer 32 and the p-side pad electrode 33 are formed by vacuum chamber after forming the ridge 30 by p-type annealing treatment and etching. Further, the n-side electrode 34 is formed on the lower surface of the n-type (0001) plane GaN substrate 10 by vacuum chamber.

A method of forming the cavity facets constituting the nitride-based semiconductor laser device 100 (see FIG. 1) and the dielectric multilayer films will be now described.

First, dotted scribed lines are formed on prescribed portions, except the ridge 30, of a wafer formed with the aforementioned semiconductor laser structure by laser scribing or mechanical scribing. Then, a pair of the cavity facets (the light emitting surface 1 and the light reflecting surface 2) are formed by cleaving the wafer along the scribed lines. Thereafter, the wafer in a bar state provided with the cavity facets is introduced into an electron cyclotron resonance (ECR) sputtering film forming apparatus.

Further, ECR plasma is applied to the light emitting surface 1 (see FIG. 1) constituted by a cleavage plane for 5 minutes, thereby cleaning the light emitting surface 1. The ECR plasma is generated under a condition of microwave output of 500 W in an N₂ gas atmosphere of about 0.02 Pa. At this time, the light emitting surface 1 is slightly etched. At this time, high-frequency power (RF power) is not applied to a sputtering target. Thereafter, the dielectric multilayer film 40 is formed on the surface of the light emitting surface 1.

According to the first embodiment, the AlN film 41 is first formed on the surface of the light emitting surface 1 by ECR plasma, as shown in FIG. 3. The ECR plasma is generated under a condition of microwave output of 500 W in an atmosphere where N₂ gas and Ar gas flow in the flow ranges of about 3 to 5 sccm and about 15 to 25 sccm. Then, the AlO_{X}N_{Y} film 42 is formed on the surface of the AlN film 41. When forming the AlO_{X}N_{Y} film 42, high-frequency power (RF power) of 500 W is applied to a sputtering target, thereby depositing the AlO_{X}N_{Y} film 42 while forming the roughness on the interface 3 between the AlN film 41 and the AlO_{X}N_{Y} film 42. N₂ gas, O₂ gas and Ar gas flow in the flow ranges of about 2 sccm to about 6 sccm, about 0.1 sccm to about 4 sccm and about 15 to 25 sccm, respectively, and the flow ratio of N₂ gas and O₂ gas is changed in the aforementioned range, thereby controlling the composition ratio of oxygen and nitrogen in the AlO_{X}N_{Y} film 42. Thus, the dielectric multilayer film 40 is formed.

Thereafter, the Al₂O₃ film 51 is formed on the surface of the dielectric multilayer film 40 (see FIG. 1) by ECR plasma.

Similarly to the aforementioned step of cleaning the light emitting surface 1, ECR plasma is applied to the light reflecting surface 2 (see FIG. 1) constituted by a cleavage plane for 5 minutes, thereby cleaning the light reflecting surface 2. At this time, the light reflecting surface 2 is slightly etched. When applying plasma, high-frequency power (RF power) is not applied to a sputtering target. Thereafter the AlN film 61, the Al₂O₃ film 62, the AlN film 63, the Al₂O₃ film 64, the SiO₂ film 65 and the multilayer reflecting film 66 are successively stacked on the light reflecting surface 2 by ECR plasma, thereby forming the dielectric multilayer film 60 (see FIG. 1).

Finally, the wafer in the form of a bar is divided into device along the cavity direction, thereby forming a large number of the separated nitride-based semiconductor laser devices 100.

According to the first embodiment, as hereinabove described, the AlN film 41 and the AlO_{X}N_{Y} film 42 are so formed in this order on the surface of the light emitting surface 1 that the interface 3 has the roughness, whereby the AlN film 41 and the AlO_{X}N_{Y} film 42 are in contact with each other through the interface 3 having the roughness, and hence the AlN film 41 and the AlO_{X}N_{Y} film 42 can be in contact with each other through a wider surface area due to formation of the roughness as compared with a case where the AlN film 41 and the AlO_{X}N_{Y} film 42 are in contact with each other on an flat contact interface with no roughness. Thus, adhesiveness between the AlN film 41 and the AlO_{X}N_{Y} film 42 can be further improved.

The AlN film 41 and the AlO_{X}N_{Y} film 42 are formed on the surface of the light emitting surface 1, whereby a reflectance for the laser beam emitted from the light emitting surface 1 can be easily controlled by adjusting the thickness of the AlO_{X}N_{Y} film 42. Thus, the nitride-based semiconductor laser device 100 allowing higher output can be easily formed.

According to the first embodiment, the plurality of projecting portions or recess portions which the AlO_{X}N_{Y} film 42 has are fitted into the plurality of recess portions or projecting portions which the AlN film 41 on the interface 3, so that the roughness of the interface 3 is formed, whereby the AlN film 41 and the AlO_{X}N_{Y} film 42 are stacked in contact with each other with no clearance through the pluralities of recess portions and projecting portions formed on the respective interface 3 sides, and hence adhesiveness between the AlN film 41 and the AlO_{X}N_{Y} film 42 can be reliably obtained.

According to the first embodiment, the roughness of the interface 3 is formed by the pluralities of recess portions 3a and projecting portions 3b, and the maximum value H1 of the height from the bottom portion of each recess portion 3a to the top portion of the projecting portions 3b adjacent to the recess portion 3a on the interface 3 is set to H1<λ/n1 and H1<λ/n2 when the wavelength of the laser beam emitted by the active layer 25 is λ, and the average refractive indices of the AlN film 41 and the AlO_{X}N_{Y} film 42 are n1 and n2, respectively, whereby the size of the pluralities of projecting and recess portions on the interface 3 (height from the bottom portion of each recess portion 3a to the top portion of the projecting portions 3b adjacent to the recess portion 3a) is smaller than λ/n1 and λ/n2. Thus, the laser beam emitted from the light emitting surface 1 is transmitted through the interface 3 without being influenced by the state of the roughness and then transmitted through the AlO_{X}N_{Y} film 42. Consequently, the reflectance control function of the AlO_{X}N_{Y} film 42 set to have a desirable reflectance can be easily inhibited from being influenced by the roughness of the interface 3.

According to the first embodiment, the interface 3 has the roughness which is set to H1<λ/n1 and H1<λ/n2 described later, whereby the reflectance for the laser beam on the interface 3 between the AlN film 41 and the AlO_{X}N_{Y} film 42 is reduced, and hence the laser beam can be effectively emitted from the light emitting surface 1.

According to the first embodiment, the nitrogen composition ratio (Y) in the AlO_{X}N_{Y} film 42 is higher than the oxygen composition ratio (X) (X<Y), whereby the AlO_{X}N_{Y} film 42 can be formed on the surface of the AlN film 41 in the state where the interface 3 between the AlO_{X}N_{Y} film 42 and the AlN film 41 has the roughness, when the light emitting surface 1 is subjected to facet coating treatment. Consequently, the AlO_{X}N_{Y} film 42 can be formed in a state where adhesiveness with the AlN film 41 is excellent.

The nitrogen composition ratio of the AlO_{X}N_{Y} film 42 is higher than the oxygen composition ratio, and hence the quantity of diffusion of oxygen contained in the AlO_{X}N_{Y} film 42 to the AlN film 41 can be suppressed. Thus, diffusion of oxygen from the AlN film 41 to the semiconductor element layer 20 is suppressed, and hence COD on the light emitting surface 1 can be suppressed.

According to the first embodiment, the thickness (about 10 nm) of the AlN film 41 is smaller than the thickness (about 30 nm) of the AlO_{X}N_{Y} film 42, whereby stress of the AlN film 41 (nitride film) in contact with the light emitting surface 1 can be kept small. Thus, separation of the AlN film 41 from the light emitting surface 1 or separation of the AlO_{X}N_{Y} film 42 from the AlN film 41 can be suppressed.

According to the first embodiment, the Al₂O₃ film 51 formed on the surface of the AlO_{X}N_{Y} film 42 on the side opposite to the light emitting surface 1 is provided, whereby the reflectance for the laser beam emitted from the light emitting surface 1 can be easily controlled by adjusting the thickness of the Al₂O₃ film 51. Thus, the nitride-based semiconductor laser device 100 allowing higher output can be easily formed.

According to the first embodiment, the AlO_{X}N_{Y} film 42 and the Al₂O₃ film 51 contain the same Al element, whereby adhesiveness between the AlO_{X}N_{Y} film 42 and the Al₂O₃ film 51 can be improved. The insulating properties of the AlO_{X}N_{Y} film 42 and the Al₂O₃ film 51 can be improved, since a nitride and an oxide containing Al each have an excellent insulating property.

According to the first embodiment, the semiconductor element layer 20 including the active layer 25 is made of a nitride-based semiconductor. Thus, breakage of the cavity facet (light emitting surface 1) on the light-emitting side especially resulting from heat generation in laser beam emission can be effectively suppressed in the nitride-based semiconductor laser device 100 having a short lasing wavelength of about 405 nm and emitting a high-energy laser beam.

In the manufacturing process of the first embodiment, the AlO_{X}N_{Y} film 42 is formed on the surface of the AlN film 41 by ECR plasma, whereby the interface 3 between the AlN film 41 and the AlO_{X}N_{Y} film 42 can be easily formed to have the roughness.

In the manufacturing process of the first embodiment, the cleaved light emitting and reflecting surfaces 1 and 2 are cleaned by applying the ECR plasma, whereby the nitride-based semiconductor laser device 100 in which deterioration of the cavity facets in the vicinity of the optical waveguide or COD is suppressed by cleaning can be easily formed.

In the manufacturing process of the first embodiment, the AlN film 41 is formed on the surface of the light emitting surface 1 in the state of generating the ECR plasma in the N₂ gas atmosphere and the flow ratio of N₂ gas and O₂ gas is thereafter adjusted, so that the AlO_{X}N_{Y} film 42 is formed on the surface of the AlN film 41 formed with roughness while forming the roughness on the surface of the AlN film 41, whereby the AlO_{X}N_{Y} film 42 covering this roughness can be easily stacked while roughness is formed on the surface of the AlN film 41 when forming the AlO_{X}N_{Y} film 42.

In the manufacturing process of the first embodiment, the AlO_{X}N_{Y} film 42 is formed on the surface of the AlN film 41 in the state of applying high-frequency power (RF power) to generate the ECR plasma, whereby the roughness for adhering the AlO_{X}N_{Y} film 42 to the surface of the AlN film 41 can be easily formed.

### Second Embodiment

A second embodiment will be described with reference to FIGS. 2, 4 and 5. According to the second embodiment, a dielectric multilayer film 70 in which a nitride film and an oxynitride film are multilayered is formed also on a light reflecting surface 2 side dissimilarly to the aforementioned first embodiment. The light reflecting surface 2 is an example of the “second cavity facet” in the present invention.

According to the second embodiment, the dielectric multilayer film 70 in which an AlN film 71 having a thickness of about 10 nm in contact with the light reflecting surface 2 and an AlO_{X}N_{Y} film 72 having a thickness of about 30 nm in contact with the AlN film 71 are formed successively from a side closer to the light reflecting surface 2 is formed on light reflecting surface 2 of a nitride-based semiconductor laser device 200, as shown in FIG. 4. According to the second embodiment, the AlN film 71 and the AlO_{X}N_{Y} film 72 each have a function of suppressing alteration of the dielectric multilayer film 70 itself and the light reflecting surface 2 due to a thermal influence or light absorption following emission of a laser beam. The AlN film 71 and the AlO_{X}N_{Y} film 72 are examples of the “fourth insulating film” and the “fifth insulating film” in the present invention, respectively, and the dielectric multilayer film 70 shown in FIG. 4 is constituted by the “fourth insulating film” and the “fifth insulating film” in the present invention.

According to the second embodiment, when an interface 4 on which the AlN film 71 and the AlO_{X}N_{Y} film 72 are in contact with each other is microscopically viewed, the interface 4 has roughness by a plurality of recess portions 4a and a plurality of projecting portions 4b as viewed from the AlO_{X}N_{Y} film 72 side, as shown in FIG. 5. In other words, the plurality of recess portions or projecting portions formed on the AlN film 71 are fitted into the plurality of projecting portions or recess portions formed on the AlO_{X}N_{Y} film 72 with no clearance, thereby forming the roughness of the interface 4. Therefore, the pluralities of recess portions 4a and projecting portions 4b of the interface 4 in FIG. 5 are the pluralities of recess portions and projecting portions which the AlN film 71 has as well as the pluralities of projecting portions and recess portions which the AlO_{X}N_{Y} film 72 has, and this shows that the AlN film 71 and the AlO_{X}N_{Y} film 72 are in contact with each other on the interface 4 in an improved adhesive state. The interface 4 is an example of the “second interface” in the present invention.

This roughness is formed to have planar spread along a width direction (direction B in FIG. 2) and a thickness direction (direction C) of the laser device formed with the light reflecting surface 2 on the interface 4 where the AlN film 71 and the AlO_{X}N_{Y} film 72 are in contact with each other.

A maximum value H2 (see FIG. 5) of a height from each recess portion 4a to the projecting portion 4b forming the interface 4 is set to preferably have the relations of H2<λ/n3 and H2<λ/n4, when refractive indices of the AlN film 71 and the AlO_{X}N_{Y} film 72 are n3 (=about 2.10) and n4 (=in the range of about 1.60 to about 2.10), respectively. According to the second embodiment, therefore, the roughness is so formed that an average value of the height from the bottom portion of each recess portion 4a to the top portion of the projecting portion 4b is about 5 nm. Thus, a laser beam reflected on the light reflecting surface 2 can be reflected toward an inner portion of the semiconductor element layer 20 with no influence of the roughness of the interface 4. The maximum value H2 of the height from the bottom portion of each recess portion 4a to the top portion of the projecting portion 4b forming the interface 4 is preferably H2<about 193 nm.

According to the second embodiment, the AlO_{X}N_{Y} film 72 is so formed that a nitrogen composition ratio (Y) is higher than an oxygen composition ratio (X) (X<Y) in addition to the AlO_{X}N_{Y} film 42. Thus, the interface 4 between the AlN film 71 and the AlO_{X}N_{Y} film 72 is formed to easily have the roughness.

According to the second embodiment, a dielectric multilayer film 80 in which an Al₂O₃ film 81 having a thickness of about 60 nm in contact with the dielectric multilayer film 70, an SiO₂ film 82 having a thickness of about 140 nm in contact with the Al₂O₃ film 81, and a multilayer reflecting film 83, in contact with the SiO₂ film 82, having a thickness of about 720 nm, formed by alternately stacking six SiO₂ films each having a thickness of about 70 nm as a low refractive index film and six ZrO₂ films each having a thickness of about 50 nm as a high refractive index film are formed is formed on a surface of the dielectric multilayer film 70 on a side opposite to the light reflecting surface 2. The multilayer reflecting film 83 has a function of controlling a reflectance, and the light reflecting surface 2 side is set to have a high reflectance of about 98% for the laser beam due to the multilayer reflecting film 83. The Al₂O₃ film 81 and the SiO₂ film 82 are each an example of the “sixth insulating film” in the present invention, and the multilayer reflecting film 83 is an example of the “seventh insulating film” in the present invention. The dielectric multilayer film 80 shown in FIG. 4 is constituted by the “sixth insulating film” and the “seventh insulating film” in the present invention.

The remaining structure of the nitride-based semiconductor laser device 200 according to the second embodiment is similar to that of the aforementioned first embodiment. As to a manufacturing process for the nitride-based semiconductor laser device 200 according to the second embodiment, the AlN film 71 and the AlO_{X}N_{Y} film 72 are stacked in this order on the surface of the light reflecting surface 2 through a manufacturing process similar to that of the aforementioned first embodiment, thereby forming the dielectric multilayer film 70. Thus, the interface 4 is formed to have the roughness.

According to the second embodiment, as hereinabove described, the AlN film 71 and the AlO_{X}N_{Y} film 72 are so formed in this order on the surface of the light reflecting surface 2 that the interface 4 has the roughness, whereby the AlN film 71 and the AlO_{X}N_{Y} film 72 are in contact with each other through the interface 4 having the roughness, and hence the AlN film 71 and the AlO_{X}N_{Y} film 72 can be in contact with each other through a wider surface area due to formation of the roughness as compared with a case where the AlN film 71 and the AlO_{X}N_{Y} film 72 are in contact with each other on an flat contact interface with no roughness. Thus, adhesiveness between the AlN film 71 and the AlO_{X}N_{Y} film 72 can be further improved on the light reflecting surface 2, in addition to the light emitting surface 1.

According to the second embodiment, the maximum value H2 of the height from the bottom portion of each recess portion 4a to the top portion of the projecting portions 4b adjacent to the recess portion 4a on the interface 4 is set to H2<λ/n3 and H2<λ/n4, when the roughness of the interface 4 is formed by the pluralities of recess portions 4a and projecting portions 4b, and the average refractive indices of the AlN film 71 and the AlO_{X}N_{Y} film 72 are n3 and n4, respectively, whereby the size of the pluralities of projecting and recess portions on the interface 4 (height from the bottom portion of each recess portion 4a to the top portion of the projecting portions 4b adjacent to the recess portion 4a) is smaller than λ/n3 and λ/n4. Thus, the laser beam emitted from the light reflecting surface 2 is transmitted through the interface 4 without being influenced by the state of the roughness and then transmitted through the AlO_{X}N_{Y} film 72. Consequently, the reflectance control function of the multilayer reflecting film 83 set to have a desirable reflectance can be easily inhibited from being influenced by the roughness of the interface 4.

According to the second embodiment, the nitrogen composition ratio (Y) in the AlO_{X}N_{Y} film 72 is higher than the oxygen composition ratio (X) (X<Y), whereby the AlO_{X}N_{Y} film 72 can be formed on the surface of the AlN film 71 in the state where the interface 4 between the AlO_{X}N_{Y} film 72 and the AlN film 71 has the roughness, when the light reflecting surface 2 is subjected to facet coating treatment. Consequently, the AlO_{X}N_{Y} film 72 can be formed in a state where adhesiveness with the AlN film 71 is excellent.

According to the second embodiment, the thickness (about 10 nm) of the AlN film 71 is smaller than the thickness (about 30 nm) of the AlO_{X}N_{Y} film 72, whereby stress of the AlN film 71 (nitride film) in contact with the light reflecting surface 2 can be kept small. Thus, separation of the AlN film 71 from the light reflecting surface 2 or separation of the AlO_{X}N_{Y} film 72 from the AlN film 71 can be suppressed.

According to the second embodiment, the nitride-based semiconductor laser device 200 comprises the Al₂O₃ film 81 and the SiO₂ film 82 formed on the surface of the AlO_{X}N_{Y} film 72 on the side opposite to the light reflecting surface 2, whereby the reflectance for the laser beam emitted from the light reflecting surface 2 can be easily controlled by adjusting the respective thicknesses of the Al₂O₃ film 81 and the SiO₂ film 82. Thus, the nitride-based semiconductor laser device 200 allowing higher output can be easily formed.

According to the second embodiment, the AlO_{X}N_{Y} film 72, the Al₂O₃ film 81 and the SiO₂film 82 contain the same Al element, whereby adhesiveness between the AlO_{X}N_{Y} film 72 and the Al₂O₃film 81, and adhesiveness between the Al₂O₃ film 81 and the SiO₂ film 82 can be improved. The insulating properties of the AlO_{X}N_{Y} film 72 and the Al₂O₃ film 81 can be improved since an oxynitride and an oxide containing Al each have an excellent insulating property.

According to the second embodiment, the nitride-based semiconductor laser device 200 comprises the multilayer reflecting film 83, obtained by alternately stacking the six SiO₂ films and the six ZrO₂ films, formed on the surface of the SiO₂film 82 on the side opposite to the light reflecting surface 2, whereby the reflectance for the laser beam emitted from the light reflecting surface 2 can be easily controlled by adjusting the thickness of the multilayer reflecting film 83.

The remaining effects of the second embodiment are similar to those of the aforementioned first embodiment.

### First Modification of Second Embodiment

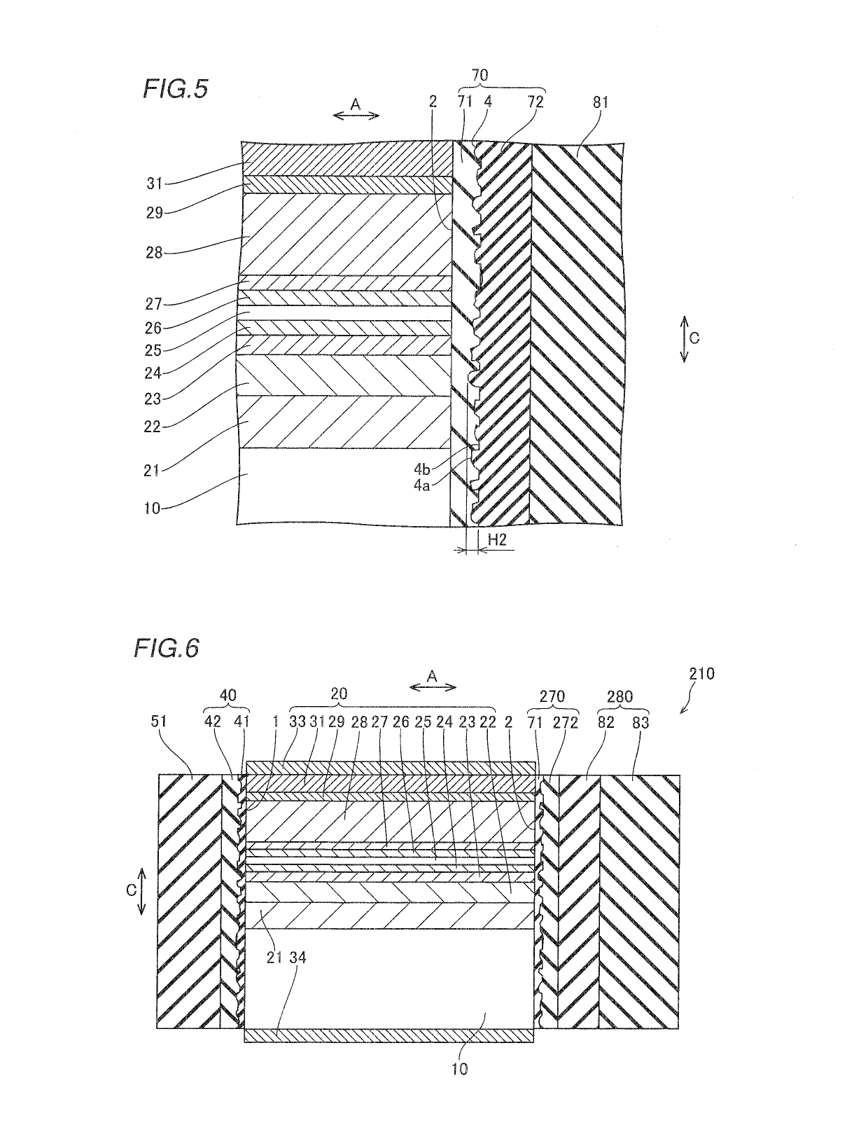

A first modification of the second embodiment will be described with reference to FIG. 6. In the first modification of the second embodiment, no Al₂O₃ film 81 is formed between an AlO_{X}N_{Y} film 272 and an SiO₂ film 82, dissimilarly to the aforementioned second embodiment.

According to the first modification of the second embodiment, a dielectric multilayer film 270 in which an AlN film 71 having a thickness of about 10 nm and an AlO_{X}N_{Y} film 272 having a thickness of about 60 nm are formed successively from a side closer to a light reflecting surface 2 is formed on the light reflecting surface 2 of a nitride-based semiconductor laser device 210, as shown in FIG. 6. The AlO_{X}N_{Y} film 272 is an example of the “fifth insulating film” in the present invention, and the dielectric multilayer film 270 shown in FIG. 6 is constituted by the “fourth insulating film” and the “fifth insulating film” in the present invention.

Further, a dielectric multilayer film 280 in which an SiO₂ film 82 having a thickness of about 140 nm and a multilayer reflecting film 83, having a thickness of about 720 nm, formed by alternately stacking six SiO₂ films each having a thickness of about 70 nm and six ZrO₂ films each having a thickness of about 50 nm are formed is formed on a surface of the dielectric multilayer film 270 on a side opposite to the light reflecting surface 2. The light reflecting surface 2 side is kept to have a reflectance of about 98% for a laser beam due to the dielectric multilayer film 280. The dielectric multilayer film 280 shown in FIG. 6 is constituted by the “sixth insulating film” and the “seventh insulating film” in the present invention.

The remaining structure and manufacturing process of the nitride-based semiconductor laser device 210 according to the first modification of the second embodiment are similar to those of the aforementioned second embodiment.

According to the first modification of the second embodiment, as hereinabove described, the dielectric multilayer film 280 is formed to be in contact with the AlO_{X}N_{Y} film 272 (thickness of about 60 nm) of the dielectric multilayer film 270, whereby since no Al₂O₃ film 81 is formed, the manufacturing process in forming the dielectric multilayer film 270 can be simplified as compared with the dielectric multilayer film 70 according to the aforementioned second embodiment. Further, a total thickness of a facet coating film constituted by the dielectric multilayer film 270 and the dielectric multilayer film 280 can be reduced.

### Second Modification of Second Embodiment

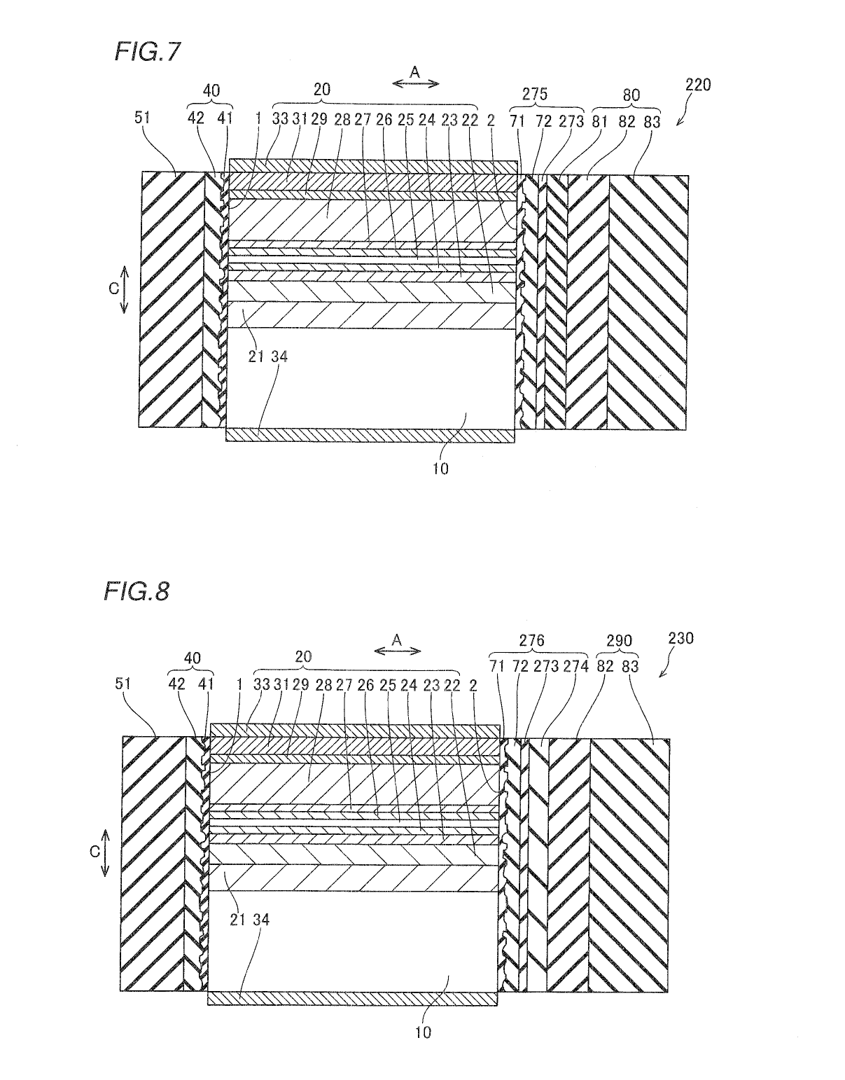

A second modification of the second embodiment will be described with reference to FIG. 7. In the second modification of the second embodiment, an AlN film is further formed between an AlO_{X}N_{Y} film 72 and an Al₂O₃ film 81, dissimilarly to the aforementioned second embodiment.

According to the second modification of the second embodiment, a dielectric multilayer film 275 in which an AlN film 71 having a thickness of about 10 nm, an AlO_{X}N_{Y} film 72 having a thickness of about 30 nm and an AlN film 273 having a thickness of about 10 nm are formed successively from a side closer to a light reflecting surface 2 is formed on the light reflecting surface 2 of a nitride-based semiconductor laser device 220, as shown in FIG. 7. The AlN film 273 is an example of the “sixth insulating film” in the present invention. The dielectric multilayer film 275 shown in FIG. 7 includes the “fourth insulating film”, the “fifth insulating film” and a part of the “sixth insulating film” in the present invention, and the dielectric multilayer film 80 includes the “seventh insulating film” and a part of the “sixth insulating film” in the present invention.

The remaining structure and manufacturing process of the nitride-based semiconductor laser device 220 according to the second modification of the second embodiment are similar to those of the aforementioned second embodiment.

According to the second modification of the second embodiment, as hereinabove described, the dielectric multilayer film 275 is constituted by the AlN film 71, the AlO_{X}N_{Y} film 72 and the AlN film 273, whereby AlN which is a material for suppressing diffusion of oxidation can further suppress diffusion of oxygen contained in the Al₂O₃ film 81 of the dielectric multilayer film 80 or the like toward the light reflecting surface 2.

### Third Modification of Second Embodiment

A third modification of the second embodiment will be described with reference to FIG. 8. In the third modification of the second embodiment, an AlN film and an AlON film in place of an Al₂O₃ film 81 is formed in this order between the AlO_{X}N_{Y} film 72 and the SiO₂film 82, dissimilarly to the aforementioned second embodiment.

According to the third modification of the second embodiment, a dielectric multilayer film 276 in which an AlN film 71 having a thickness of about 10 nm, an AlO_{X}N_{Y} film 72 having a thickness of about 30 nm, an AlN film 273 having a thickness of about 10 nm and an AlO_{X}N_{Y} film 274 having a thickness of about 60 nm are formed successively from a side closer to a light reflecting surface 2 is formed on the light reflecting surface 2 of a nitride-based semiconductor laser device 230, as shown in FIG. 8. A dielectric multilayer film 290 constituted by the SiO₂ film 82 and a multilayer reflecting film 83 (six pairs of an SiO₂ film and a ZrO₂ film) is formed to be in contact with the dielectric multilayer film 276. The AlO_{X}N_{Y} film 274 is an example of the “sixth insulating film” in the present invention. The dielectric multilayer film 276 shown in FIG. 8 includes the “fourth insulating film”, the “fifth insulating film” and a part of the “sixth insulating film” in the present invention, and the dielectric multilayer film 290 includes the “seventh insulating film” and a part of the “sixth insulating film” in the present invention.

The remaining structure and manufacturing process of the nitride-based semiconductor laser device 230 according to the third modification of the second embodiment are similar to those of the aforementioned second embodiment.

According to the third modification of the second embodiment, as hereinabove described, the dielectric multilayer film 276 is constituted by the AlN film 71, the AlO_{X}N_{Y} film 72, the AlN film 273 and the AlO_{X}N_{Y} film 274, whereby since the nitride film (AlN film 273) and the oxide film (SlO₂ film 82) are stacked through the oxynitride film (AlO_{X}N_{Y} film 274), adhesiveness between the nitride film and the oxynitride film on the contact interface and adhesiveness between the oxynitride film and the oxide film on the contact interface can be improved, in addition to the effects of the aforementioned second modification of the second embodiment.

### Third Embodiment

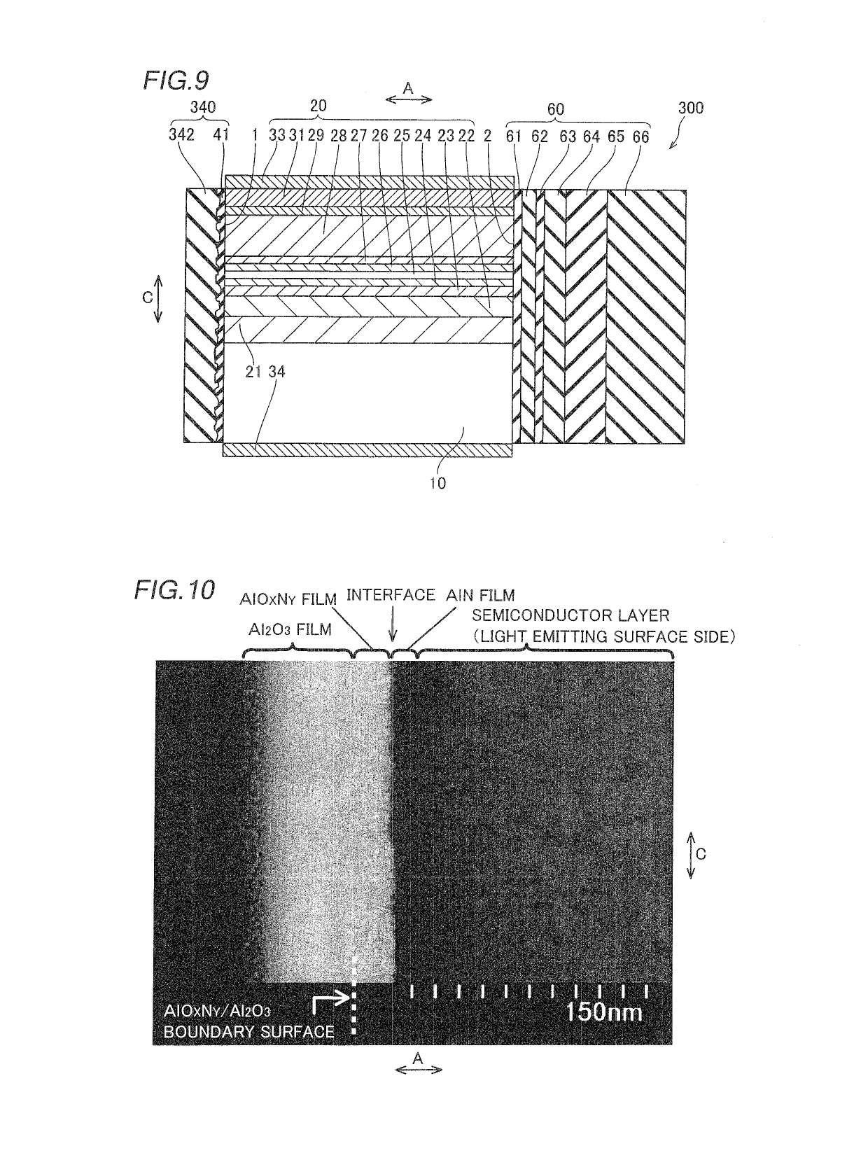

A third embodiment will be described with reference to FIG. 9. In this third embodiment, only a dielectric multilayer film 340 constituted by a nitride film and an oxynitride film is formed on a light emitting surface 1, dissimilarly to the aforementioned first embodiment.

According to the third embodiment, only the dielectric multilayer film 340 in which an AlN film 41 having a thickness of about 10 nm in contact with a light emitting surface 1 and an AlO_{X}N_{Y} film 342 having a thickness of about 70 nm in contact with the AlN film 41 are formed successively from a side closer to the light emitting surface 1 is formed on the light emitting surface 1 of the nitride-based semiconductor laser device 300, as shown in FIG. 9. In other words, according to the third embodiment, no Al₂O₃ film 51 shown in the aforementioned first embodiment is formed on an outermost surface of the facet coating film (dielectric multilayer film 340). The light emitting surface 1 is set to have a reflectance of about 8% for a laser beam due to the dielectric multilayer film 340. The remaining structure (structure of the facet coating film on the light reflecting surface 2 side and the like) and manufacturing process of the nitride-based semiconductor laser device 300 according to the third embodiment are similar to those of the aforementioned first embodiment.

According to the third embodiment, as hereinabove described, only the dielectric multilayer film 340 constituted by the AlN film 41 and the AlO_{X}N_{Y} film 342 is formed on the light emitting surface 1, whereby since no Al₂O₃ film 51 according to the aforementioned first embodiment is formed, the manufacturing process in forming the dielectric multilayer film 340 can be simplified, and a total thickness of the dielectric multilayer film 340 can be reduced.

### EXAMPLE

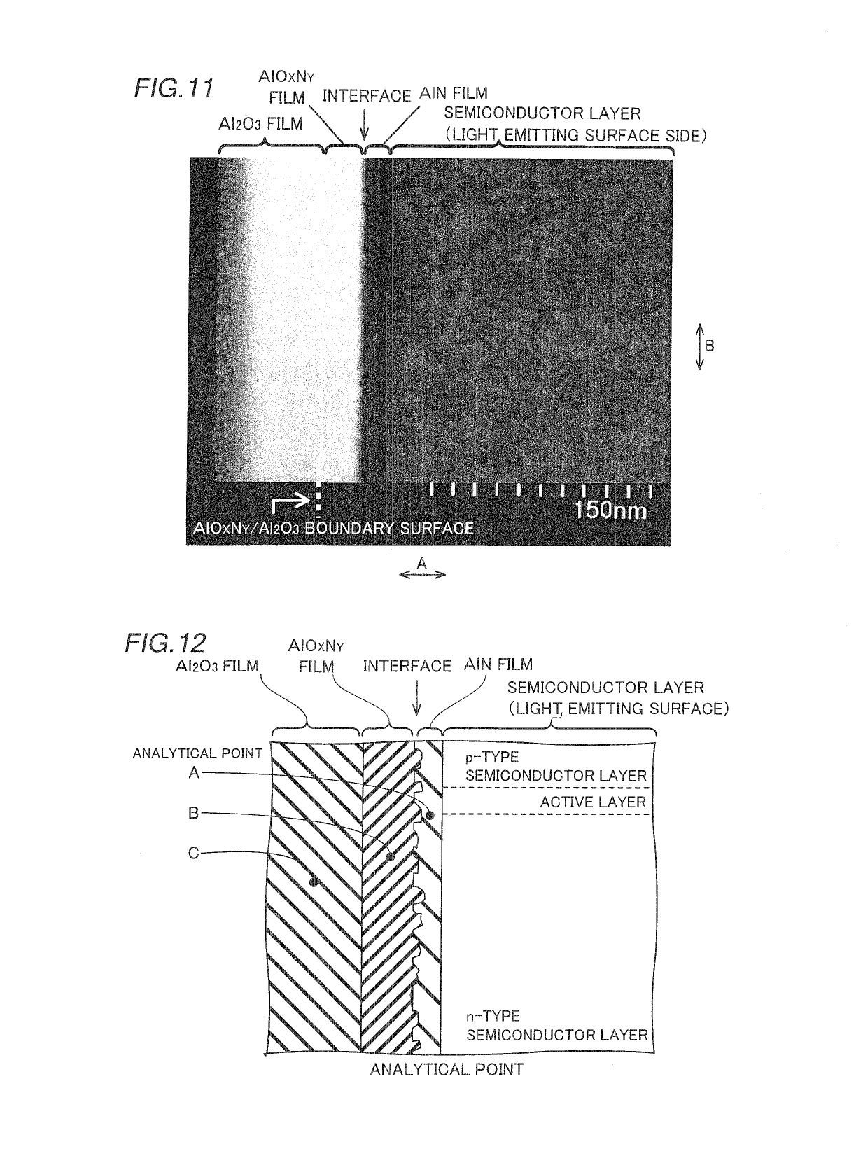

A confirmatory experiment conducted for confirming the effects of the aforementioned first embodiment will be described with reference to FIGS. 1 and 10 to 13. FIG. 10 is a photomicrograph obtained when observing a state of a dielectric multilayer film along a width direction (direction B in FIG. 2) of a nitride-based semiconductor laser device from a side surface of the device, and FIG. 11 is a photomicrograph obtained when observing a state of a dielectric multilayer film along a thickness direction (direction C in FIG. 2) of the nitride-based semiconductor laser device from a lower surface of the device.

In this confirmatory experiment, a nitride-based semiconductor laser device 100 (see FIG. 1) according to Example corresponding to the aforementioned first embodiment was prepared through a manufacturing process similar to that of the aforementioned first embodiment. At this time, an AlN film and an AlO_{X}N_{Y} film are stacked successively from a side closer to a light emitting surface 1 by ECR plasma, and an Al₂O₃ film was thereafter formed on a surface of the AlO_{X}N_{Y} film to perform facet coating treatment of the light emitting surface 1.

In the nitride-based semiconductor laser device 100 according to the aforementioned Example, a composition of oxygen and nitrogen in each dielectric film (analytical points A to C: see FIG. 12) of the light emitting surface 1 was measured for analysis. The composition was analyzed by energy-dispersive X-ray spectroscopy (EDS).

Further, a stress value of each dielectric film was also investigated. More specifically, the AlN film, the AlO_{X}N_{Y} film and the Al₂O₃ film were independently formed on an Si substrate under a condition (temperature, pressure, flow ratio of atmosphere gas, and the like) similar to the formation condition of each dielectric film in the aforementioned Example. Then, stress values of the respective dielectric films were calculated on the basis of measurement data of a warp of an Si substrate formed with no dielectric films and warps of Si substrates formed with respective dielectric films.

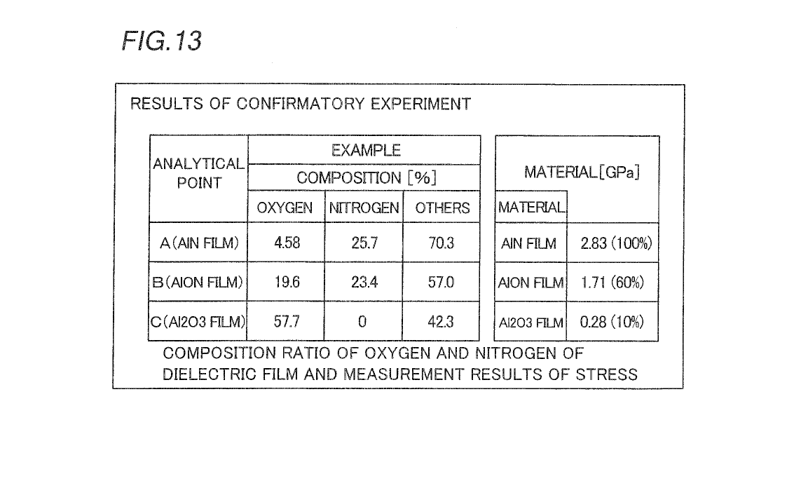

Referring to FIG. 13, when comparing the composition ratio of oxygen and nitrogen on the analytical point A, it has been confirmed that the ratio of nitrogen was remarkable because the analytical point A was the AlN film. On the analytical point B, on the other hand, it has been confirmed that the AlO_{X}N_{Y} film in which the ratio of nitrogen was higher than that of oxygen was formed. At this time, it has been confirmed that roughness by a plurality of recess portions and a plurality of projecting portions was formed on an interface between the AlN film and the AlO_{X}N_{Y} film, as shown in FIGS. 10 and 11. Therefore, the AlO_{X}N_{Y} film can be conceivably stacked on the surface of the AlN film under a condition where the roughness is easily formed by forming the AlO_{X}N_{Y} film in which the ratio of nitrogen was higher than that of oxygen on the surface of the AlN film by ECR plasma. In FIGS. 10 and 11, although definition was slightly deteriorated when attaching the photomicrographs as drawings and hence a boundary surface (dotted position in the drawing) between the AlO_{X}N_{Y} film and the Al₂O₃ film is difficult to be discriminated, the observation results from which the boundary surface between the AlO_{X}N_{Y} film and the Al₂O₃ film can be discriminated was obtained from actual photomicrographs.

From the results of calculation of stress of the respective dielectric films, difference in stress value between the AlN film and the Al₂O₃ film was 10 times. On the other hand, it has been confirmed that the AlO_{X}N_{Y} film had an approximate intermediate stress value (about 60%) between the AlN film and the Al₂O₃ film. Therefore, it has been proved that the AlO_{X}N_{Y} film was able to relax large stress difference between the AlN film and the Al₂O₃ film by holding the AlO_{X}N_{Y} film between the AlN film and the Al₂O₃ film in the nitride-based semiconductor laser device 100 (see FIG. 1) according to the aforementioned Example. Thus, it has been confirmed that a dielectric multilayer film allowing improvement of heat radiability on the light emitting surface 1 by bringing the AlN film (nitride film) into contact with the light emitting surface 1 without film separation and suitable control of the reflectance of an emitted laser beam by arranging Al₂O₃ film (oxide film) on the outermost surface was able to be formed.

Although the present invention has been described and illustrated in detail, it is clearly understood that the same is by way of illustration and example only and is not to be taken by way of limitation, the spirit and scope of the present invention being limited only by the terms of the appended claims.

For example, while the semiconductor element layer 20 is formed by the nitride-based semiconductor layer in each of the aforementioned first to third embodiments, the present invention is not restricted to this but the semiconductor element layer may be formed by a semiconductor material other than the nitride-based semiconductor layer.

While the AlN film and the AlO_{X}N_{Y} film are formed in this order on the cavity facets (light emitting and reflecting surfaces 1 and 2) by ECR plasma in the manufacturing process of each of the aforementioned first to third embodiments, the present invention is not restricted to this but the AlO_{X}N_{Y} film may be formed in a state where the roughness is formed on the surface of the AlN film by etching after forming the AlN film. The roughness where a maximum value H of the height from the bottom portion of each recess portion to the top portion of the projecting portion adjacent to the recess portion is H <λ/n (n: average refractive index of each insulating film) can be formed by properly adjusting the etching condition.

While the Al₂O₃ film 51 which is the oxide film is employed for the insulating film controlling the reflectance on the light emitting surface 1 side in the aforementioned first embodiment, the present invention is not restricted to this but the insulating film may be formed by an oxidized compound containing an Si element, a Zr element, a Ta element, an Hf element and a Nb element. For example, an Si₃N₄ film, other than the aforementioned oxide film, which is a nitride film may be formed. The Si₃N₄ film is an example of the “third insulating film” in the present invention. For example, an AlON film or an SiON film, different from the aforementioned oxide film and nitride film, which is an oxynitride film may be formed.

While the facet coating film on the light reflecting surface 2 side is formed similarly to the aforementioned first embodiment (dielectric multilayer film 60) in the aforementioned third embodiment, the present invention is not restricted to this but the facet coating film on the light reflecting surface 2 side may be formed similarly to the facet coating film (combination of the dielectric multilayer films 70 and 80) employed in the aforementioned second embodiment or the facet coating film (combination of the dielectric multilayer films 270 and 280) employed in the aforementioned first modification of the second embodiment. Alternately, the facet coating film on the light reflecting surface 2 side may be formed similarly to the facet coating film (combination of the dielectric multilayer films 275 and 80) employed in the aforementioned second modification of the second embodiment or the facet coating film (combination of the dielectric multilayer films 276 and 80) employed in the aforementioned third modification of the second embodiment.

While the AlO_{X}N_{Y} film 342 is formed to have a thickness of about 70 nm in each of the aforementioned third embodiment and the modification thereof, the present invention is not restricted to this but the reflectance of the light emitting surface 1 is periodically changed by the thickness of the formed AlO_{X}N_{Y} film 342, and hence the thickness of the AlO_{X}N_{Y} film 342 for obtaining a desired reflectance may be other than 70 nm described above.

While the multilayer reflecting film (66 or 83) controlling the reflectance on the light reflecting surface 2 side is formed by alternately stacking the six SiO₂ films and the six ZrO₂ films in each of the aforementioned first to third embodiment, the present invention is not restricted to this but the SiO₂ films and the ZrO₂ films may be alternately stacked in numbers other than six. Further, different two types of insulating films having other refractive indices other than the SiO₂ film and the ZrO₂ film may be combined as the multilayer reflecting film. For example, a multilayer reflecting film made of SiO₂films and Ta₂O₅ films may be employed, or a multilayer reflecting film made of SiO₂films and Hf₂O films may be employed. Alternately, a multilayer reflecting film made of SiO₂ films and Nb₂O₅ films may be employed, or a multilayer reflecting film made of SiO₂ films and TiO₂ films may be employed. Further, a multilayer reflecting film made of Al₂O₃ films and Ta₂O₅ films may be employed or a multilayer reflecting film made of Al₂O₃ films and Hf₂O films may be employed. Alternately, a multilayer reflecting film made of Al₂O₃ films and Nb₂O₅ films may be employed, or a multilayer reflecting film made of Al₂O₃ films and TiO₂ films may be employed.

While the semiconductor element layer 20 is so formed on the main surface of the n-type (0001) plane GaN substrate 10 that the ridge 30 extends in a [1-100] direction in each of the aforementioned first to third embodiment, the present invention is not restricted to this but the semiconductor element layer may be formed on an n-type GaN substrate having a main surface, the plane orientation of which is an a-plane ((11-20) plane) or an m-plane ((1-100) plane) so that the nitride-based semiconductor laser device is formed. In particular, when the semiconductor element layer is formed on the main surface of the nonpolar face such as the a-plane or the m-plane, the semiconductor element layer is formed with a ridge extending along a [0001] direction and a (0001) plane and a (000-1) plane of the semiconductor element layer are the “first cavity facet” and the “second cavity facet” in the present invention, respectively. The semiconductor element layer is grown on the a-plane or the m-plane of the n-type GaN substrate, whereby a piezoelectric field caused in the active layer can be further reduced, and hence a nitride-based semiconductor laser device having more improved luminous efficiency can be obtained. When the semiconductor element layer is formed on a main surface of the aforementioned c-plane, a ridge extending along a [11-20] direction can be formed on the semiconductor element layer, for example. In this case, a (11-20) plane and a (−1-120) place of the semiconductor element layer are the “first cavity facet” and the “second cavity facet” in the present invention, respectively. When the semiconductor element layer is formed on the main surface of the aforementioned c-plane, a ridge extending along a [1-100] direction can be formed on the semiconductor element layer. In this case, a (1-100) plane and a (−1-1100) plane of the semiconductor element layer are the “first cavity facet” and the “second cavity facet” in the present invention, respectively.

What is claimed is:

1. A semiconductor laser device comprising:
a semiconductor element layer having a light emitting layer;
a cavity facet formed on an end of said semiconductor element layer of a region including said light emitting layer;
a first insulating film, made of AlN, formed on a surface of said facet on a light-emitting side in said cavity facet; and
a second insulating film, made of AlO_{X}N_{Y} (0<X<1.5, 0<Y≦1), formed by depositing said second insulating film on a surface on an opposite side of said first insulating film to said facet on said light-emitting side, wherein
an interface between said first insulating film and said second insulating film has a recess portion and a projection portion.

2. The semiconductor laser device according to claim 1, wherein
said recess portion and said projection portion include a plurality of recess portions and a plurality of projection portions,
a maximum value H1 of a height from a bottom portion of said first recess portion to a top portion of said first projection portion adjacent to said first recess portion on said first interface is set to H1<λ/n1 and H1<λ/n2 when a wavelength of a laser beam emitted by said light emitting layer is λ and average refractive indices of said first insulating film and said second insulating film are n1 and n2, respectively.

3. The semiconductor laser device according to claim 1, wherein
said AlO_{X}N_{Y} satisfies X<Y.

4. The semiconductor laser device according to claim 1, further comprising a third insulating film, made of either an oxide film or a nitride film, formed on a surface on an opposite side of said second insulating film to said light-emitting side facet.

5. A method of manufacturing a semiconductor laser device, comprising steps of:
forming a semiconductor element layer having a light emitting layer;
forming cavity facets on ends of said semiconductor element layer on a region including said light emitting layer;
forming a first insulating film made of AlN on a surface of a light-emitting side facet of said cavity facet; and
forming a second insulating film made of AlO_{X}N₁ (0<X<1.5, 0<Y≦1) by depositing said second insulating film on a surface of said first insulating film so that an interface between said first insulating film and said second insulating film has a first recess portion and a first projection portion.

6. The method of manufacturing a semiconductor laser device according to claim 5, wherein
said step of forming said second insulating film includes a step of forming said second insulating film by ECR plasma so that an interface between said first insulating film and said second insulating film has a first recess portion and a first projection portion.
